(19) United States
(12) Patent Application Publication
(10) Pub. No.: US 2024/0081005 A1
(43) Pub. Date: Mar. 7, 2024

(54) FLEXIBLE SCREEN

(71) Applicant: SYNCMOLD ENTERPRISE CORP., New Taipei City (TW)

(72) Inventors: Chun-Hao HUANG, New Taipei City (TW); Ching-Hui YEN, New Taipei City (TW); Chien-Cheng YEH, New Taipei City (TW)

(21) Appl. No.: 18/325,375

(22) Filed: May 30, 2023

Related U.S. Application Data
(60) Provisional application No. 63/403,187, filed on Sep. 1, 2022.

(30) Foreign Application Priority Data
Jan. 9, 2023 (TW) 112200262

(51) Int. Cl. H05K 5/02

(52) U.S. Cl. CPC H05K 5/0217

(57) ABSTRACT

A flexible screen comprises a multi-layer display structure and a covering structure. The multi-layer display structure includes an outer surface and an inner surface opposite to the outer surface, and the inner surface faces towards the foldable electronic device. The covering structure is disposed on the outer surface of the multi-layer display structure and includes a substrate layer and a plurality of nano-protrusions. The nano-protrusions are formed in array on at least one side of the substrate layer. The flexible screen can transform between an unfolded state and a folded state, and a bending section is partially formed when the flexible screen is in the folded state. The nano-protrusions located in the bending section can release the stress generated in the bending section when the flexible screen transform between the unfolded state and the folded state.

### CROSS REFERENCE TO RELATED APPLICATION

This application claims the benefit of U.S. Provisional Application Ser. No. 63/403,187 filed on Sep. 1, 2022, and the benefit of Taiwan Patent Application Serial No. 112200262 filed on Jan. 9, 2023. The entirety of each Application is incorporated herein by reference.

### BACKGROUND OF THE INVENTION

### 1. Field of the Invention

The present invention relates to a flexible screen, especially a flexible screen that can reduce creases caused by stress concentration in a foldable electronic device.

### 2. Description of Related Art

Foldable electronic devices have become increasingly popular on the market. However, one of the most common issues with foldable electronic devices is the formation of irreversible creases on the screen after repeated switching between folded and unfolded states, which can affect the user's visual experience. It is obvious that improving screen visibility and preventing creases caused by stress concentration are still necessary for the foldable electronic devices.

Moreover, the present invention further provides a flexible screen with a unique flexible screen structure. This structure is distinct from those structures of prior arts and comprises an array of conical nano-protrusions formed on the top layer of the flexible screen.

### SUMMARY OF THE INVENTION

An objective of the present invention is to provide a flexible screen, which can be added a special covering structure on the outermost layer of the flexible screen. The covering structure has a plurality of nano-protrusion structures distributed in an array, which can further eliminate the stress concentration generated at the local bending place when the foldable electronic device is folded, thereby minimizing the formation of the creases on the screen.

To achieve the above-mentioned objective, the present invention discloses a flexible screen being disposed on a foldable electronic device. The flexible screen comprises a multi-layer display structure and a covering structure. The multi-layer display structure includes an outer surface and an inner surface opposite to the outer surface, and the inner surface faces towards the foldable electronic device. The covering structure is disposed on the outer surface of the multi-layer display structure and includes a substrate layer and a plurality of nano-protrusions. The nano-protrusions are formed in array on at least one side of the substrate layer. The flexible screen is able to transform between an unfolded state and a folded state, and wherein when the flexible screen is in the folded state, the flexible screen is partially formed with a bending section. The nano-protrusions located in the bending section can release the stress generated in the bending section.

In one embodiment of the present invention, when the flexible screen is in the unfolded state, a first longitudinal direction and a second longitudinal direction perpendicular to each other are defined relative to the outer surface, and the nano-protrusions are arranged in array with intervals along the first longitudinal direction and second longitudinal direction.

In one embodiment of the present invention, the pitch of any two adjacent nano-protrusions is less than 250 nanometers (nm).

In one embodiment of the present invention, the thickness of the covering structure is approximate 1000 nanometers (nm).

In one embodiment of the present invention, the flexible screen further comprises a supporting plate, which attaches to the inner surface of the multi-layer display structure, and is arranged on the foldable electronic device.

In one embodiment of the present invention, the bending section further comprises a first bending segment, a second bending segment, and a third bending segment. The second bending segment is located between the first bending segment and the third bending segment, wherein the first bending segment, the second bending segment and the third bending segment are continuously arranged. The cross section of the bending section is in a droplet shape when the flexible screen is in the folded state.

In one embodiment of the present invention, the nano-protrusions are formed at least on the first bending segment, the second bending segment, and the third bending segment, and are respectively formed on the opposite sides of the substrate layer that away from the multi-layer display structure and toward the multi-layer display structure.

In one embodiment of the present invention, each of the nano-protrusions is in conical shape and has a height and a base diameter with an aspect ratio greater than 1.

In one embodiment of the present invention, the aspect ratio of the nano-protrusions located in the second bending segment is greater than that of the nano-protrusions located in the first bending segment and the third bending segment.

In one embodiment of the present invention, the pitch of the adjacent nano-protrusions located in the second bending segment is smaller than that of the adjacent nano-protrusions located in the first bending segment and the third bending segment.

### BRIEF DESCRIPTION OF THE DRAWINGS

FIG. 1 is a schematic view of the foldable electronic device with the flexible screen in the unfolded state according to the present invention;

FIG. 2 is an exploded view of the flexible screen according to the present invention;

FIG. 3 is a schematic view of the assembly of the flexible screen and the foldable electronic device according to the present invention;

FIG. 4 is a top plan view of the flexible screen according to the present invention;

FIG. 5 is a partial cross-sectional view of the covering structure of the flexible screen according to the present invention;

FIG. 6 is a partial schematic view of the covering structure of the flexible screen according to the present invention;

FIG. 7 is a partial side view of the flexible screen in the folded state according to the present invention;

FIG. 8 is a plan view of the flexible screen of another embodiment according to the present invention; and

FIG. 9 is a partial cross-sectional view of the foldable electronic device with the flexible screen in the folded state according to the present invention;

### DETAILED DESCRIPTION OF THE PREFERRED EMBODIMENT

Reference will now be made in detail to the present embodiments of the invention, examples of which are illustrated in the accompanying drawings, and are not intended to limit the present invention, applications or particular implementations described in these embodiments. Wherever possible, the same reference numbers are used in the drawings and the description to refer to the same or like parts. It shall be appreciated that, in the following embodiments and the attached drawings, elements unrelated to the present invention are omitted from depiction; and dimensional relationships among individual elements in the attached drawings are provided only for ease of understanding, but not to limit the actual scale.

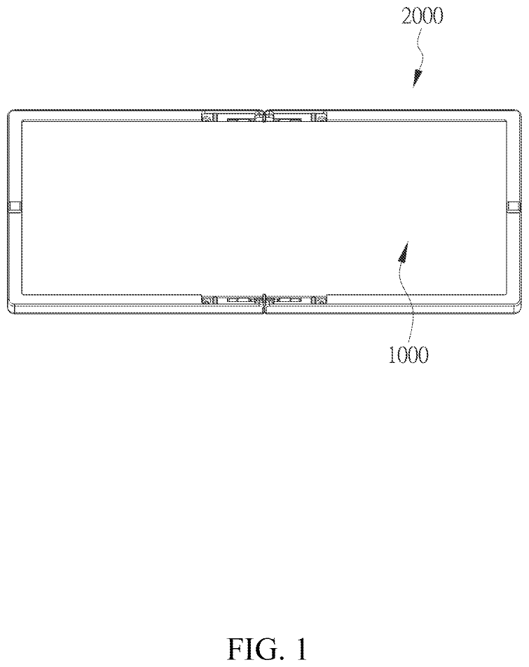

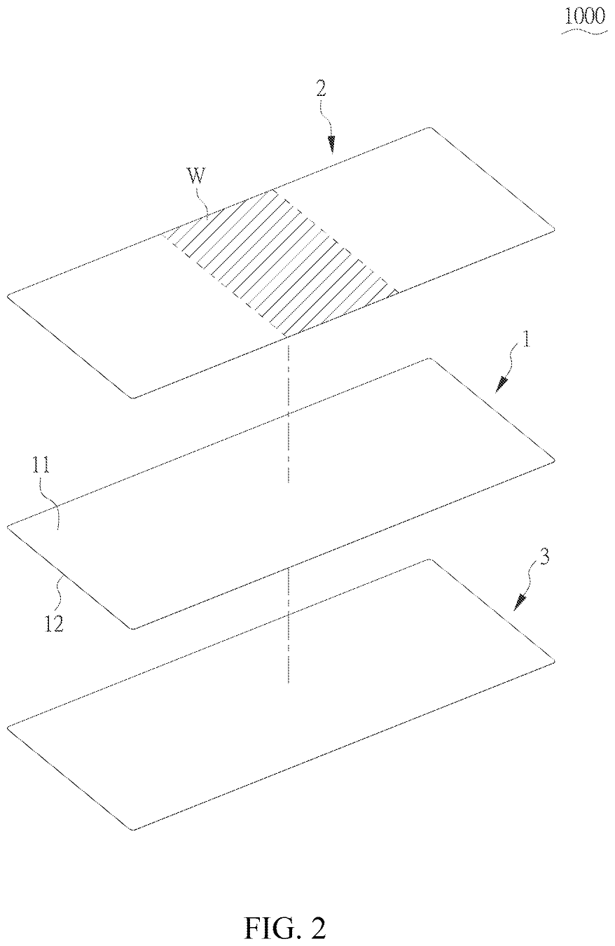

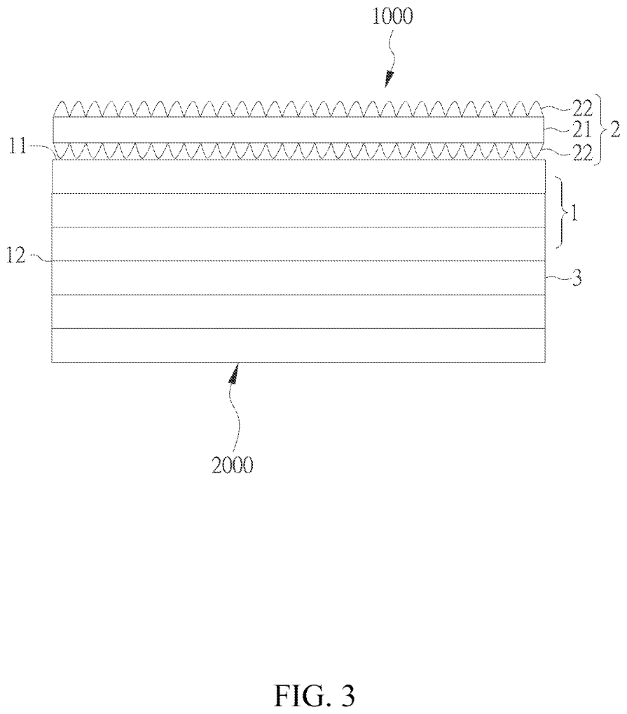

First, as shown in FIG. 1 to FIG. 3, the schematic view of the foldable electronic device 2000 with the flexible screen 1000 in the unfolded state is shown in FIG. 1. FIG. 2 is an exploded view of the flexible screen 1000 of the present invention. FIG. 3 is a schematic view of the assembly of the flexible screen 1000 and the foldable electronic device 2000 of the present invention. The flexible screen 1000 is disposed on the foldable electronic device 2000. The flexible screen 1000 comprises a multi-layer display structure 1, a covering structure 2, and a supporting plate 3. Specifically, the covering structure 2 is arranged on the multi-layer display structure 1. The multi-layer display structure 1 is arranged between the covering structure 2 and the supporting plate 3, and the supporting plate 3 is arranged on the foldable electronic device 2000. The supporting plate 3 is located at the bottom of the flexible screen 1000 and is able to support for the overall structure of the flexible screen 1000 as well as during folding.

Continuing from the above, multi-layer display structure 1 includes an outer surface 11 and an inner surface 12 opposite to the outer surface 11. The outer surface 11 is away from the foldable electronic device 2000 and is provided for the covering structure 2 being disposed thereon. The inner surface 12 faces toward the foldable electronic device 2000 and is connected to the foldable electronic device 2000. The multi-layer display structure 1 is a composite multi-layered structure that may include, for example, a covering plate, an OLED display layer, a polarizer layer, a back plate, and at least one adhesive layer (not shown in the figure). However, the covering plate, the OLED display layer, the polarizer layer, and the back plate are all flexible, and any adjacent layer structure can be attached through the adhesive layer to form a single module. In this embodiment, the assembly sequence of the multi-layer display structure 1 from top to bottom can be the adhesive layer, the OLED display layer, and the adhesive layer (as shown in FIG. 3). The assembly position and the number of layers can be adjusted according to actual requirements, which is not limited thereto.

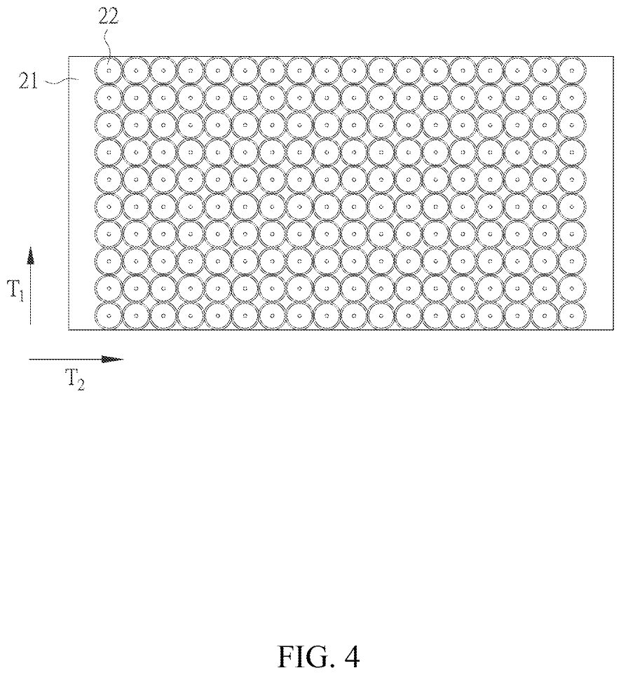

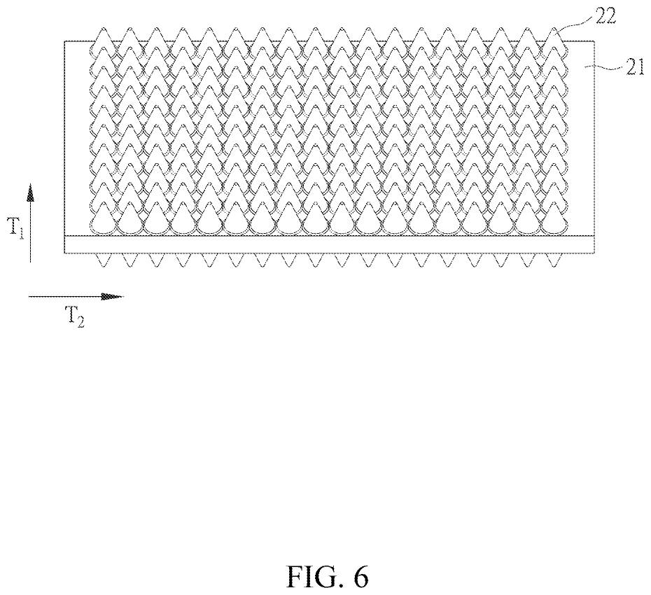

Hereafter, the covering structure 2 is further illustrated. Please referring to FIG. 4 and FIG. 6, the covering structure 2 includes a substrate layer 21 and a plurality of nano-protrusions 22, and the nano-protrusions 22 are formed on the substrate layer 21. Specifically, a first longitudinal direction T1 and a second longitudinal direction T2 are defined when the flexible screen 1000 is in the unfolded state. The first longitudinal direction T1 and the second longitudinal direction T2 are perpendicular to each other (relative to the outer surface 11). The nano-protrusions 22 are arranged in an array distribution with intervals along the first longitudinal directions T1 and the second longitudinal directions T2. In other words, the arrangement of the array distribution is such that the intervals between the nano-protrusions 22 along the first longitudinal direction T1 and the intervals between the nano-protrusions 22 along the second longitudinal direction T2 are equidistant. When the covering structure 2 is folded, the nano-protrusions 22 are stretched or compressed due to the external forces applied, and the concave space generated by two adjacent nano-protrusions 22 can be utilized to alleviate and release the stress generated when the flexible screen 1000 transforms between the unfolded state and folded state.

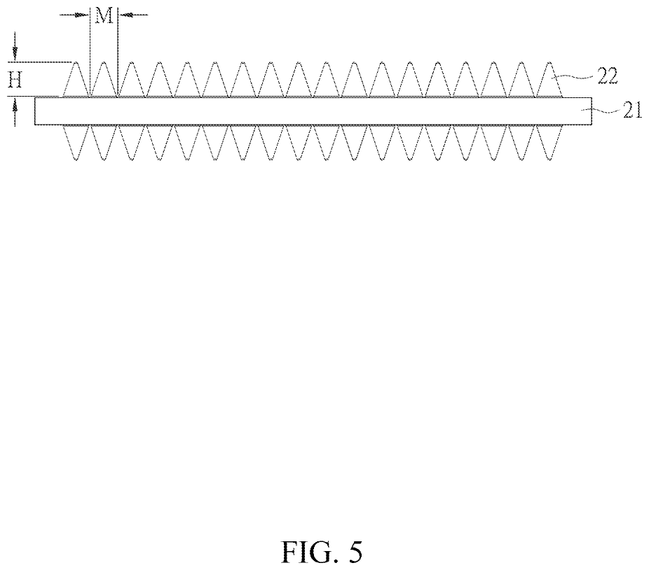

Furthermore, referring to FIG. 5, each of the nano-protrusions 22 is in a conical shape with a height H and a base diameter M. The height H refers to the distance from the vertex to the base of the conical shape of the nano-protrusion 22, and the base of the nano-protrusion 22 is connected to the surface of the substrate layer 21. The base diameter M is the diameter length of the base of the nano-protrusion 22. It should be noted that the height H and the base diameter M can respectively define an aspect ratio. In this embodiment, the aspect ratio value is greater than 1, and when the multi-layer display structure 1 is folded, the nano-protrusions 22 of the covering structure 2 can provide improved endurance against bending deformation.

In this embodiment, the pitch of any two adjacent nano-protrusions 22 (i.e., the distance between the centers of the bases of adjacent nano-protrusions) is less than 250 nanometers, and the nano-protrusions 22 are formed on both the upper and lower sides of the substrate layer 21 of the covering structure 2. The overall thickness of the covering structure 2 is approximately 1000 nanometers. In other words, the nano-protrusion 22 is a nanoscale particle structure, which cannot be directly observed by the naked eyes. The nano-protrusion 22 has unique material properties of high transparency and anti-reflective.

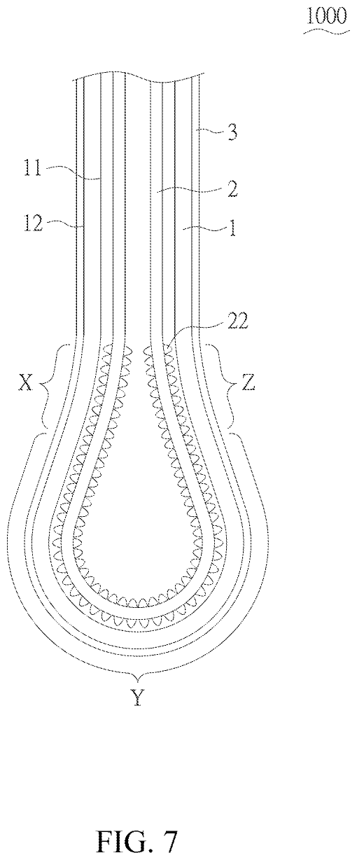

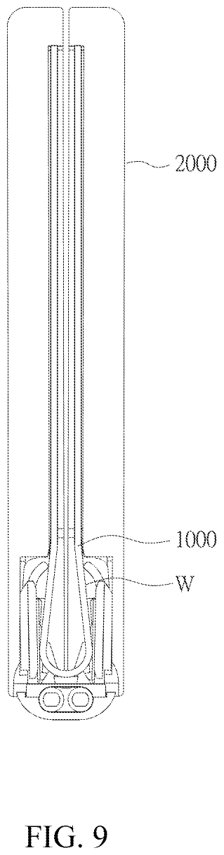

The operation of the flexible screen 1000 is further described with reference to FIG. 7 to FIG. 9. When the external force is applied to the foldable electronic device 2000, the foldable electronic device 2000 and the attached flexible screen 1000 can transform between the unfolded state (as shown in FIG. 1) and the folded state (as shown in FIG. 9). The covering structure 2, the multi-layer display structure 1, and the supporting plate 3 of the flexible screen 1000 fold simultaneously. At this time, a bending section W is partially formed when the flexible screen 1000 is in the folded state. In detail, the bending section W further includes a first bending segment X, a second bending segment Y and a third bending segment Z. The second bending segment Y is located between the first bending segment X and the third bending segment Z. When the flexible screen 1000 is in the folded state, the bending section W exhibits a cross-section that is roughly in the shape of a droplet (as shown in FIG. 7).

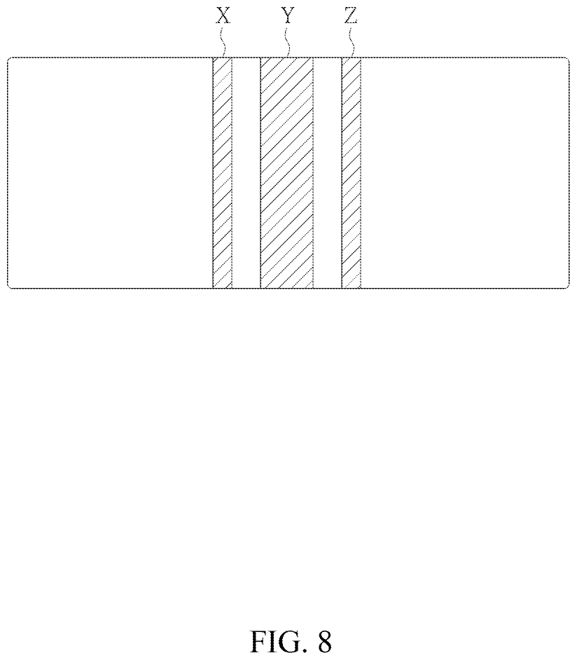

In this embodiment, the first bending segment X, the second bending segment Y and the third bending segment Z are continuously arranged. In another embodiment, as shown in FIG. 8, the hatched area indicates the arrangement of the nano-protrusions 22, wherein the first bending segment X, the second bending segment Y and the third bending segment Z may be discontinuously arranged. The first bending segment X, the second bending segment Y and the third bending segment Z can be located at the local bending zone where the flexible screen 1000 bears the bending stress in the folded state (as shown in FIG. 9). Considering the structural support and flexibility of the bending section W, the spacing and position of each bending segment can be adjusted according to the actual bending requirements, which is not limited thereto.

As mentioned above, the nano-protrusions 22 are formed with at least in the first bending segment X, the second bending segment Y and the third bending segment Z. Moreover, the nano-protrusions 22 are respectively formed on the side of the substrate layer 21 facing away from the multi-layer display structure 1 and the opposite side facing towards the multi-layer display structure 1. It should be noted that the aspect ratio of the nano-protrusions 22 in the first bending segment X, the second bending segment Y and the third bending segment Z, or the pitch of any two adjacent nano-protrusions 22, can be further designed and adjusted. These adjustments are based on the stress generated when the covering structure 2 is stretched or compressed during bending. For example, because the bending degree being generated in the second bending segment Y is higher than the bending degrees of the first bending segment X and of the third bending segment Z, the aspect ratio of the nano-protrusions 22 in the second bending segment Y can be greater than that of the nano-protrusions 22 in the first bending segment X and the third bending segment Z, or the pitch of any two adjacent nano-protrusions 22 in the second bending segment Y is smaller than that of any two adjacent nano-protrusions 22 in the first bending segment X and the third bending segment Z, which is not limited thereto.

In another embodiment, the covering structure 2 can also be a single-sided structure, such as a structure with protrusions on only one side. The nano-protrusions 22 can be formed on a single surface of the substrate layer 21 that is parallel to the outer surface 11 (or the inner surface 12) of the multi-layer display structure 1, as long as the nano-protrusions 22 of the covering structure 2 in the first bending segment X, the second bending segment Y and the third bending segment Z can be easily bent and can withstand the stress generated during bending.

According to the above descriptions, the flexible screen of the present invention is composed of the multi-layer display layer, the covering structure and the supporting plate. The array distribution of the nano-protrusion structure on the covering structure creates a structure similar to the eye of a moth. The nano-protrusion structure can release the local bending stress generated during repeated bending of the flexible screen, and further reduce irreversible screen creases caused by stress. In addition, the flexible screen also has the effects of anti-reflective and bending resistance.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A flexible screen, being disposed on a foldable electronic device, the flexible screen comprising:
a multi-layer display structure including an outer surface and an inner surface opposite to the outer surface, and the inner surface facing towards the foldable electronic device;
a covering structure being disposed on the outer surface of the multi-layer display structure and including a substrate layer and a plurality of nano-protrusions, wherein the nano-protrusions are arranged in array on at least one side of the substrate layer;
wherein the flexible screen is able to transform between an unfolded state and a folded state, and wherein when the flexible screen is in the folded state, the flexible screen is partially formed with a bending section, and the nano-protrusions located in the bending section release the stress generated in the bending section.

2. The flexible screen as claimed in claim 1, wherein when the flexible screen is in the unfolded state, a first longitudinal direction and a second longitudinal direction perpendicular to each other are defined relative to the outer surface, and the nano-protrusions are arranged in array with intervals along the first longitudinal direction and second longitudinal direction.

3. The flexible screen as claimed in claim 2, wherein a pitch of any two adjacent nano-protrusions is less than 250 nanometers.

4. The flexible screen as claimed in claim 3, wherein a thickness of the covering structure is approximate 1000 nanometers.

5. The flexible screen as claimed in claim 4, further comprising a supporting plate, which attaches to the inner surface of the multi-layer display structure, and is arranged on the foldable electronic device.

6. The flexible screen as claimed in claim 1, wherein the bending section further includes a first bending segment, a second bending segment, and a third bending segment, the second bending segment is located between the first bending segment and the third bending segment, wherein the first bending segment, the second bending segment and the third bending segment are continuously arranged, and the bending section is in a droplet shape when the flexible screen is in the folded state.

7. The flexible screen as claimed in claim 6, wherein the nano-protrusions are formed at least on the first bending segment, the second bending segment, and the third bending segment, and are respectively formed on opposite sides of the substrate layer that away from the multi-layer display structure and toward the multi-layer display structure.

8. The flexible screen as claimed in claim 7, wherein each of the nano-protrusions is in a conical shape and has a height and a base diameter with an aspect ratio greater than 1.

9. The flexible screen as claimed in claim 8, wherein any aspect ratio of the nano-protrusions located in the second bending segment is greater than any aspect ratio of the nano-protrusions located in the first bending segment and the third bending segment.

10. The flexible screen as claimed in claim 9, wherein a pitch defined by the adjacent nano-protrusions located in the second bending segment is smaller than that of the adjacent nano-protrusions located in the first bending segment and the third bending segment.
